(19) United States
(12) Patent Application Publication
(10) Pub. No.: US 2012/0149166 A1
(43) Pub. Date: Jun. 14, 2012

(54) METHOD OF FORMING TITANIUM NITRADE (TiN) FILM, NONVOLATILE MEMORY DEVICE USING THE TiN FILM, AND METHOD OF MANUFACTURING THE NONVOLATILE MEMORY DEVICE

(76) Inventors: Young-Lim PARK, Hwaseong-si (KR); Jin-Il Lee, Seongnam-si (KR); Kyung-Min Chung, Hwaseong-si (KR); Sug-Woo Jung, Hwaseong-si (KR); Chang-Su Kim, Hwaseong-si (KR)

(21) Appl. No.: 13/301,047

(22) Filed: Nov. 21, 2011

(30) Foreign Application Priority Data
Dec. 13, 2010 (KR) 10-2010-0127107

(51) Int. Cl. H01L 21/20; H01L 21/768

(52) U.S. Cl. 438/382; 438/681; 257/E21.09; 257/E21.576

(57) ABSTRACT

A method of manufacturing a nonvolatile memory device includes forming an insulating film pattern, which includes apertures, on a substrate, forming a switching element in each of the apertures, forming a bottom electrode on the switching element by using a silicon (Si)-doped titanium nitride (TiN) film, and forming a variable resistance material pattern on the bottom electrode. The Si-doped TiN film is formed by repeatedly forming a TiN film and doping the TiN film with Si.

This application claims priority from Korean Patent Application No. 10-2010-0127107 filed on Dec. 13, 2010, the disclosure of which is hereby incorporated by reference herein in its entirety.

### BACKGROUND

1. Technical Field

Exemplary embodiments of the present invention relate to a nonvolatile memory device and a method of manufacturing the same.

2. Description of the Related Art

Examples of nonvolatile memories using resistance materials include phase-change random access memories (PRAMs), resistive RAMs (RRAMs), and magnetic RAMs (MRAMs). While dynamic RAMs (DRAMs) or flash memories store may data using charges, nonvolatile memories using resistance materials may store data using a state change of a phase-change material such as, for example, chalcogenide alloy (in the case of PRAMs), a resistance change of a variable resistance material (in the case of RRAMs), or a resistance change of a magnetic tunnel junction (MTJ) thin film according to a magnetization state of a ferromagnetic material (in the case of MRAMs).

Of such nonvolatile memories using resistance materials, for example, a PRAM includes a phase-change material. The phase-change material may have low resistance in a crystalline state and may have high resistance in an amorphous state. Therefore, the crystalline state is defined as set data or data 0, and the amorphous state is defined as reset data or data 1. In addition, the PRAM provides a write pulse such as a set pulse or a reset pulse to the phase-change material and performs a write operation using joule heat generated by the write pulse. For example, to write data 1, the phase-change material is heated above its melting temperature using the reset pulse and then rapidly cooled, so that it goes into the amorphous state. To write data 0, the phase-change material is, for example, heated to a temperature between its crystallization temperature and melting temperature for a predetermined period of time using the set pulse and then cooled, so that the phase-change material goes into the crystalline state.

A significant issue in increasing the integration density of such a PRAM is a reduction in the number of write pulses used in a write operation. To reduce the number of write pulses, various methods have been researched, including a method of scaling the size of a bottom electrode contact which is in contact with a phase-change material and a method of doping a phase-change material with nitrogen. However, these methods may be difficult to apply in an actual process. Even when the methods are applied, various defects may occur, thereby degrading the reliability characteristics of a device.

Thus, there is a need in the art for a nonvolatile memory device having increased durability characteristics and to a method of manufacturing the same.

### SUMMARY

Exemplary embodiments of the present invention provide a method of manufacturing a nonvolatile memory device with increased durability characteristics.

Exemplary embodiments of the present invention also provide a method of forming a TiN film which constitutes a nonvolatile memory device with improved durability characteristics.

Exemplary embodiments of the present invention also provide a nonvolatile memory device with increased durability characteristics.

However, exemplary embodiments of the present invention are not restricted to the ones set forth herein. Exemplary embodiments of the present invention will become more apparent to one of ordinary skill in the art by referencing the detailed description given below.

According to an exemplary embodiment of the present invention, there is provided a method of manufacturing a nonvolatile memory device, including forming an insulating film pattern, which includes apertures, on a substrate, forming a switching element in each of the apertures, forming a bottom electrode on the switching element by using a silicon (Si)-doped titanium nitride (TiN) film, and forming a variable resistance material pattern on the bottom electrode. The Si-doped TiN film is formed by repeatedly forming a TiN film and doping the TiN film with Si.

According to an exemplary embodiment of the present invention, there is provided a method of forming a titanium nitride (TiN) film, including successively performing a plurality of times a first operation of depositing a TiN precursor using an atomic layer deposition (ALD) method and making the deposited TiN precursor react with a reaction gas, and successively performing a plurality of times a second operation of making a silicon (Si) precursor react with the TiN film using the ALD method.

According to an exemplary embodiment of the present invention, a method of manufacturing a nonvolatile memory device is provided. The method includes forming a plurality of element isolation regions in a substrate of a first conductivity type to define a plurality of active regions therein, forming a plurality of word lines in the active regions, forming a first insulating pattern having a plurality of first apertures on the substrate, with the first apertures exposing a respective one of each of the word lines, forming a first semiconductor pattern and a second semiconductor pattern sequentially stacked in each of the first apertures to thereby form a vertical cell diode in each of the first apertures and on a respective one of each of the word lines, forming a diode electrode on each of the vertical cell diodes and forming a second insulating film pattern having a plurality of second apertures on the first insulating film pattern. The second apertures each expose a respective one of each of the diode electrodes. The method further includes forming a bottom electrode film formed of a silicon (Si)-doped titanium nitride (TiN) film on a top surface of the second insulating film pattern, on a top surface of each of the diode electrodes and covering sidewalls of each the second apertures, forming a third insulating film pattern on the bottom electrode film filling each of the second apertures, partially removing the bottom electrode film and the third insulating film pattern to form a bottom electrode on each of the diode electrodes and an insulating pattern within a respective one of each of the bottom electrodes, sequentially forming a phase-change material pattern and a top electrode contact on each of the bottom electrodes, forming a top insulating film pattern having contact holes therein on the substrate having the top electrode contacts, forming a bit line contact plug in each of the contact holes to contact a respective one of each of the top electrode contacts and forming a bit line on the bit line contact plugs and intersecting the word lines.

### BRIEF DESCRIPTION OF THE DRAWINGS

Exemplary embodiments of the present invention can be understood in more detail from the following description taken in conjunction with the attached drawings, in which:

FIG. 1 is a circuit diagram of a nonvolatile memory device according to an exemplary embodiment of the present invention;

FIGS. 2 through 14 are diagrams for explaining a method of manufacturing a nonvolatile memory device according to an exemplary embodiment of the present invention; and

FIGS. 15A and 15B are graphs illustrating the set-state resistance and reset-state resistance of an experimental example of the present invention and those of a comparative experimental example.

### DETAILED DESCRIPTION OF EXEMPLARY EMBODIMENTS

Exemplary embodiments of the present invention will now be described more fully hereinafter with reference to the accompanying drawings, in which exemplary embodiments of the invention are shown. Exemplary embodiments of the present invention may, however, be embodied in different forms and should not be construed as limited to exemplary embodiments set forth herein. The same reference numbers indicate the same components throughout the specification.

It will be understood that when an element or layer is referred to as being “connected to,” or “coupled to” another element or layer, it can be directly connected to or coupled to another element or layer or intervening elements or layers may be present. Like numbers refer to like elements throughout. As used herein, the term “and/or” includes any and all combinations of one or more of the associated listed items.

Hereinafter, exemplary embodiments of the present invention will be described using a phase-change random access memory (PRAM). However, exemplary embodiments of the present invention can be applied to all nonvolatile memories using resistance materials, such as, for example, resistive RAMs and magnetic RAMs.

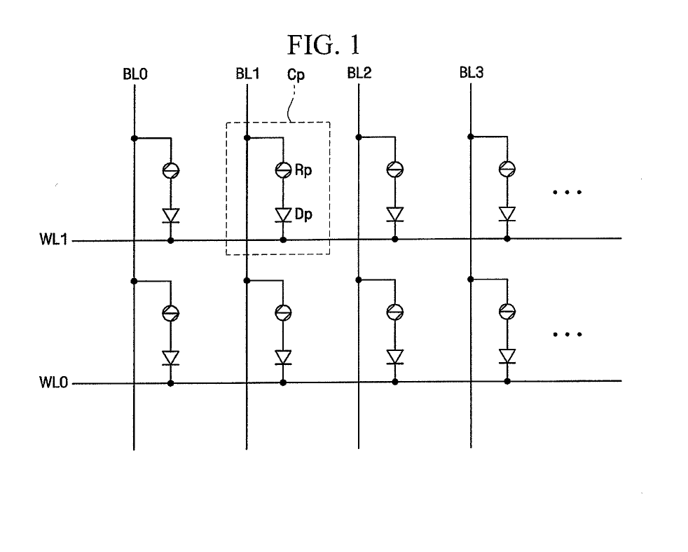

FIG. 1 is a circuit diagram of a nonvolatile memory device according to an exemplary embodiment of the present invention.

Referring to FIG. 1, the nonvolatile memory device according to the current exemplary embodiment includes, for example, a plurality of nonvolatile memory cells Cp, a plurality of bit lines BL0 through BL3, and a plurality of word lines WL0 and WL1.

The nonvolatile memory cells Cp are arranged at intersections of the word lines WL0 and WL1 and the bit lines BL0 through BL3. Each of the nonvolatile memory cells Cp includes, for example, a variable resistance material pattern having different resistances in a set state and a reset state and a switching element controlling current that flows through the variable resistance material pattern.

In the current exemplary embodiment, the variable resistance material pattern may be, but is not limited to, a phase-change element Rp which becomes crystalline or amorphous according to the current that flows therethrough and has a different resistance in each state. The phase-change element Rp may be made of various types of materials including, for example, a combination of two elements such as gallium antimonide (GaSb), indium antimonide (InSb), indium selenide (InSe), antimony tritelluride (Sb₂Te₃) or germanium telluride (GeTe), a combination of three elements such as germanium-antimony-tellurium (GeSbTe), gallium selenium telluride (GaSeTe), indium antimony telluride (InSbTe), tin antimony telluride (SnSb₂Te₄) or indium antimony germanide (InSbGe), and a combination of four elements such as silver indium antimony tellurium (AgInSbTe), germanium tin antimony telluride (GeSn)SbTe), germanium antimony selenium tulluride (GeSb(SeTe) or tellurium germanium antimony sulfide (Te₈₁Ge₁₅Sb₂S₂). For example, the phase-change element Rp may contain GeSbTe, which is a combination of germanium (Ge), antimony (Sb) and tellurium (Te).

In the current exemplary embodiment, the switching element may be, but is not limited to, a vertical cell diode Dp. Alternatively, a transistor can also be used as the switching element.

In the drawing, the phase-change element Rp is coupled to each of the bit lines BL0 through BL3, and the vertical cell diode Dp is coupled to each of the word lines WL0 and WL1. Conversely, the phase-change element Rp may be coupled to each of the word lines WL0 and WL1, and the vertical cell diode Dp may be coupled to each of the bit lines BL0 through BL3.

The operation of the nonvolatile memory device will now be described with reference to FIG. 1.

For a write operation of the nonvolatile memory device, the phase-change element Rp is heated to a temperature higher than its melting temperature Tm and then is quickly cooled. This heating and cooling sequence causes the phase-change element Rp to assume an amorphous state of logic level 1. Alternatively, the phase-change element Rp is heated to a temperature which is higher than a crystallization temperature Tx and lower than the melting temperature Tm, this temperature for the phase-change element Rp is maintained for a predetermined period of time and then cooled. This heat and cooling sequence causes the phase-change element Rp to assume a crystalline state of logic level 0. To change the phase of the phase-change element Rp, a write current in a significantly high level is supplied to the phase-change element Rp (e.g., a variable resistance material). For example, a write current of approximately 1 mA may be supplied to reset the phase-change element Rp, and a write current of about 0.6 to about 0.7 mA may be supplied to set the phase-change element Rp. The write current is supplied from a write circuit (not shown) and flows to a ground source via the bit lines BL0 and BL1 and the vertical cell diode Dp.

For a read operation of the nonvolatile memory device, a read current in a level that does not change the phase of the phase-change element Rp is supplied to the phase-change element Rp to read data stored in the phase-change element Rp. The read current is supplied from a read circuit (not shown) and flows to the ground source via the bit lines BL0 through BL3 and the vertical cell diode Dp.

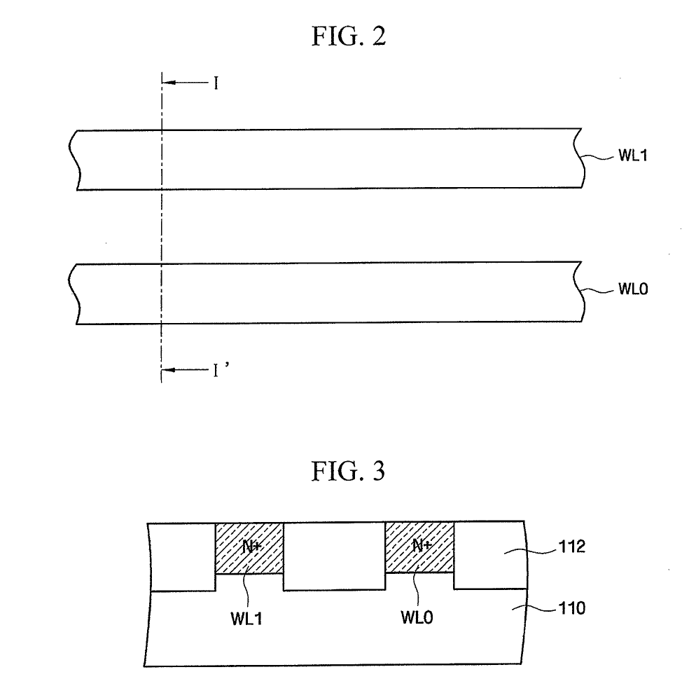

Hereinafter, a method of manufacturing a nonvolatile memory device according to an exemplary embodiment of the present invention will be described with reference to FIGS. 2 through 14. FIGS. 3, 5, 12 and 14 are cross-sectional views taken along the line I-I′ of FIGS. 2, 4, 11 and 13, respectively.

Referring to FIGS. 2 and 3, element isolation regions 112 are formed in a substrate 110 of a first conductivity type (e.g., a P type) to define a plurality of active regions. The active regions may extend in a first direction and may be parallel to each other. Impurities of a second conductivity type (e.g., an N type) are implanted into the active regions to form word lines WL0 and WL1. The substrate 110 may be, for example, a silicon substrate, a silicon-on-insulator (SOI) substrate, a gallium arsenic substrate, or a silicon germanium substrate.

While a case where the impurities of the second conductivity type are implanted into the substrate 110 of the first conductivity type to form the word lines WL0 and WL1 has been described, exemplary embodiments of the present invention are not limited to this case. For example, the word lines WL0 and WL1 may be formed by epitaxial growth. For example, a mold film pattern including a plurality of apertures which expose predetermined regions of the substrate 110 is formed on the substrate 110. Then, an epitaxial layer is formed in each of the apertures using, for example, a selective epitaxial growth (SEG) method or a solid phase epitaxial growth (SPEG) method. The impurities of the second conductivity type are ion-implanted into the whole surface of the substrate 110 on which the epitaxial layer is grown, thereby completing the word lines WL0 and WL1. While being grown using the SEG or SPEG method, if the epitaxial layer is doped in-situ with impurities, the ion-implantation process may be omitted.

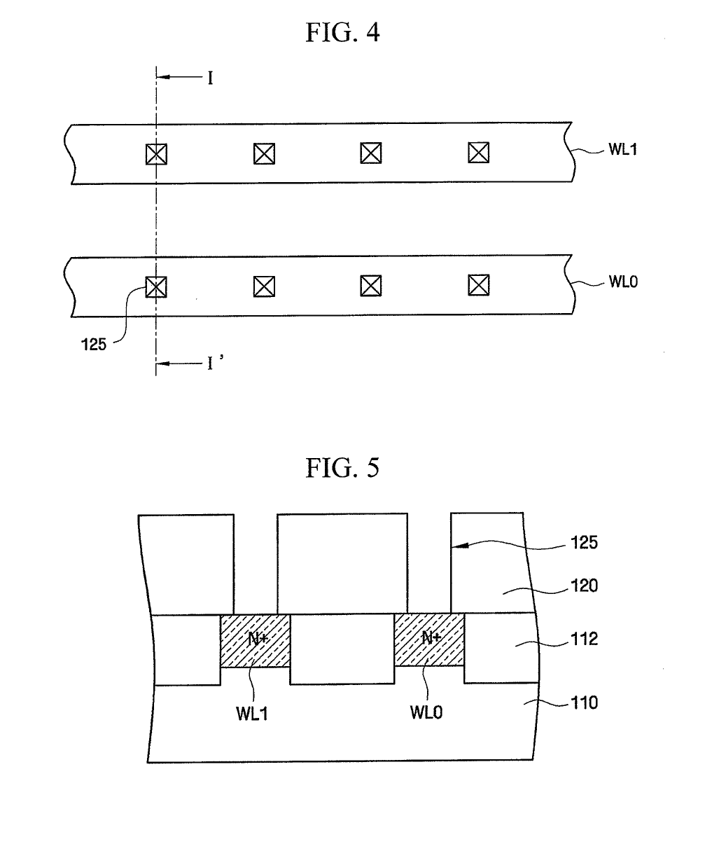

Referring to FIGS. 4 and 5, a first insulating film pattern 120 having a plurality of first apertures 125 which expose the substrate 110 is formed on the substrate 110. The first insulating film pattern 120 may be made of, for example, silicon dioxide (SiO₂), silicon nitride (SiN), or silicon oxynitride (SiON).

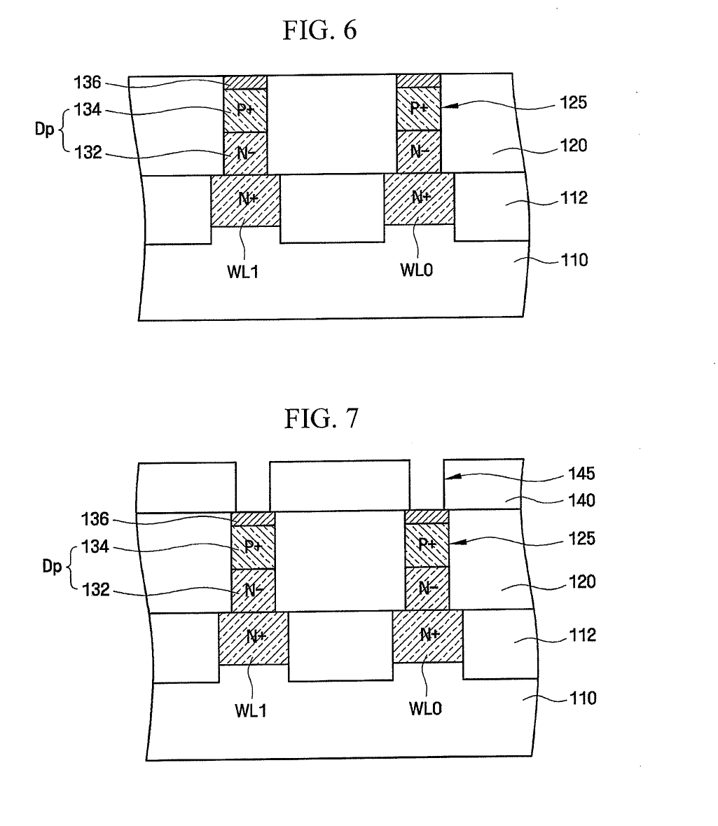

Referring to FIG. 6, first and second semiconductor patterns 132 and 134 are formed in each of the first apertures 125 to form a vertical cell diode Dp.

The first and second semiconductor patterns 132 and 134 may be formed using various methods. For example, the first and second semiconductor patterns 132 and 134 may be grown using the SEG method. For example, the first semiconductor pattern 132 may be grown using each of the word lines WL0 and WL1, which are exposed by the first apertures 125, as a seed layer, and the second semiconductor pattern 134 may be grown using the first semiconductor pattern 132 as a seed layer. Here, when the word lines WL0 and WL1 are single crystal, the grown first and second semiconductor patterns 132 and 134 are also single crystal. The first and second semiconductor patterns 132 and 134 may also be formed using, for example, the SPEG method. Next, impurities of the second conductivity type (e.g., the N type) are ion-implanted into the first semiconductor pattern 132, and impurities of the first conductivity type (e.g., the P type) are ion-implanted into the second semiconductor pattern 134. While being grown using the SEG or SPEG method, if the first and second semiconductor patterns 132 and 134 are doped in-situ with impurities, the ion-implantation process may be omitted.

The impurity concentration of the first semiconductor pattern 132 may be lower than those of the word lines WL0 and WL1, and the impurity concentration of the second semiconductor pattern 134 may be higher than that of the first semiconductor pattern 132. This is to reduce leakage current that flows through the vertical cell diode Dp when a reverse bias is applied to the vertical cell diode Dp. The reverse bias may be applied to the vertical cell diode Dp of each unselected phase-change memory cell during a write or read operation.

A diode electrode 136 may be formed on the vertical cell diode Dp. The diode electrode 136 may be made of one material selected from the group consisting of, for example, titanium (Ti), titanium silicide (TiSi), titanium nitride (TiN), titanium oxynitride (TiON), titanium tungsten (TiW), titanium aluminum nitride (TiAlN), titanium boron nitride (TiBN), tungsten (W), tungsten nitride (WN), tungsten oxynitride (WON), tungsten silicon nitride (WSiN), tungsten boron nitride (WBN), tungsten carbon nitride (WCN), silicon (Si), tantalum (Ta), tantalum silicide (TaSi), tantalum nitride (TaN), tantalum oxynitride (TaON), tantalum aluminum nitride (TaAlN), tantalum silicon nitride (TaSiN), tantalum carbonitride (TaCN), molybdenum (Mo), molybdenum nitride (MoN), molybdenum silicon nitride (MoSiN), molybdenum aluminum nitride (MoAlN), niobium nitride (NbN), zirconium silicon nitride (ZrSiN), zirconium aluminum nitride (ZrAlN), ruthenium (Ru), cobalt silicide (CoSi), nickel silicide (NiSi), a conductive carbon group, copper (Cu), and a combination of these materials.

In the current exemplary embodiment, the diode electrode 136 is formed in each of the first apertures 125 of the first insulating film pattern 120. However, exemplary embodiments of the present invention are not limited thereto. The diode electrode 136 may also be formed on each of the first apertures 125.

Referring to FIG. 7, a second insulating film pattern 140 having a plurality of second apertures 145, each exposing the diode electrode 136, is formed on the first insulating film pattern 120. The second insulating film pattern 140 may be made of, for example, SiO₂, SiN, or SiON.

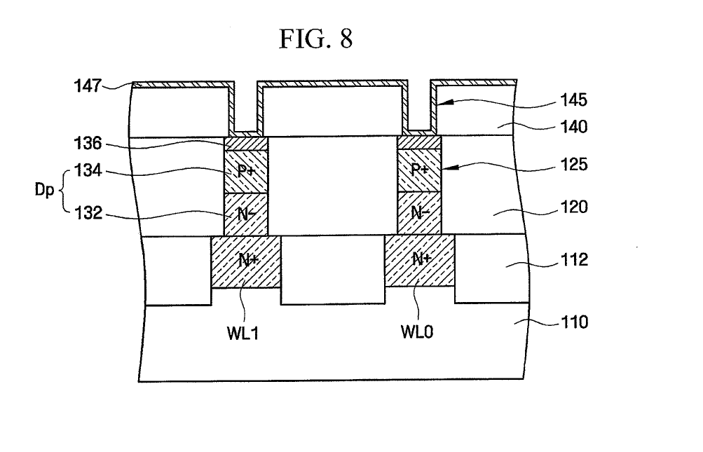

Referring to FIG. 8, a bottom electrode film 147 is formed on the second insulating film pattern 140 having the second apertures 145. The bottom electrode film 147 may be formed to cover sidewalls of the second apertures 145, a top surface of the diode electrode 136, and a top surface of the second insulating film pattern 140. In the current exemplary embodiment, a case where the bottom electrode film 147 does not completely fill the second apertures 145 is described as an example. However, exemplary embodiments of the present invention are not limited to this case. The bottom electrode film 147 may also completely fill the second apertures 145.

The bottom electrode film 147 may be made of, for example, a Si-doped TiN film. For example, the Si-doped TiN film may be formed by repeatedly forming a TiN film using an atomic layer deposition (ALD) method and doping the TiN film with Si.

A method of forming a Si-doped TiN film will now be described in detail. The method of forming a Si-doped TiN film may largely include a first operation of depositing a TiN film and a second operation of doping the deposited TiN film with Si.

In the first operation of depositing a TiN film, a TiN precursor is deposited on a substrate using, for example, the ALD method. The ALD method may be, for example, a thermal ALD method. The TiN precursor for depositing a TiN film using the ALD method may be any one of, for example, tetrakis-(dimethylamino)-titanium (TDMAT), tetrakis-(diethylamino)-titanium (TDEAT), tetrakis-(ethylmethylamino)-titanium (TEMAT), and a combination of these materials. The TiN precursor may be deposited, for example, at approximately 420° C. or below.

When the deposition of the TiN precursor on the substrate is completed, the residual TiN precursor which is not deposited on the substrate is purged. After the purging of the residual TiN precursor, a reaction gas is supplied. The reaction gas may be, for example, a ammonia (NH₃) gas, a mixed gas of hydrogen (H₂) and nitrogen (N₂), or a N₂ gas. The reaction gas reacts with the TiN precursor deposited on the substrate to form a TiN film. After the TiN film is formed, the reaction gas is purged, thereby completing the first operation.

The first operation may be repeated a number of times before the second operation is performed. For example, the first operation may be repeated x times, where x is a natural number equal to or greater than two.

In the second operation of doping the TiN film with Si, the deposited TiN film is doped with a Si precursor using, for example, the ALD method. Here, the ALD method may be, for example, the thermal ALD method. The Si precursor may be any one of, for example, bis-(tert-butylamino)-silane (BTBAS), tris-(dimethylamino)-silane (3DMAS), tetrakis-(tert-butylamino)-silane (TTBAS), and a combination of these materials. Si in the Si precursor penetrates into a TiN lattice to dope the TiN film. After the TiN film is doped with Si, the residual Si precursor unused to dope the TiN film is purged, thereby completing the second operation.

Like the first operation, the second operation may be repeated a number of times. For example, the second operation may be repeated y times, where y is a natural number equal to or greater than two. That is, a Si-doped TiN film may be formed by successively performing the first operation x times and then successively performing the second operation y times.

The number x of times that the first operation is performed and the number y of times that the second operation is performed are related to the concentration of Si in a TiN film, and the concentration of Si in the TiN film is related to the resistivity of the TiN film. Therefore, the resistivity of the Si-doped TiN film may be controlled by, for example, adjusting values of x and y.

By performing the first operation x times and the second operation y times, one cycle of a process of forming a Si-doped TiN film is completed. The thickness of the Si-doped TiN film may be adjusted by, for example, changing the number of cycles of the process of forming the Si-doped TiN film. For example, 30 to 40 cycles may be performed to form a Si-doped TiN film with a thickness of approximately 150 Å. The effects of the Si-doped TiN film will be described later.

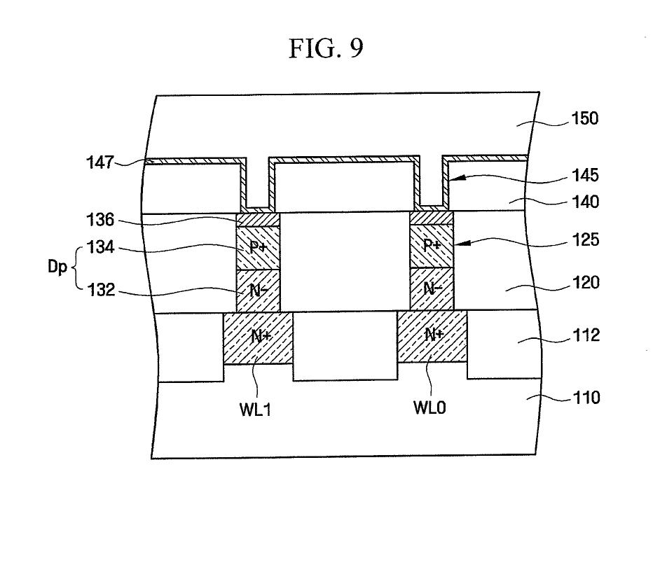

Referring to FIG. 9, a third insulating film pattern 150 may be formed on the bottom electrode film 147. In the current exemplary embodiment, the third insulating film pattern 150 fills the second apertures 145. However, exemplary embodiments of the present invention are not limited thereto. When the second apertures 145 are already completely filled with the bottom electrode film 147, the third insulating film pattern 150 may not fill the second apertures 145.

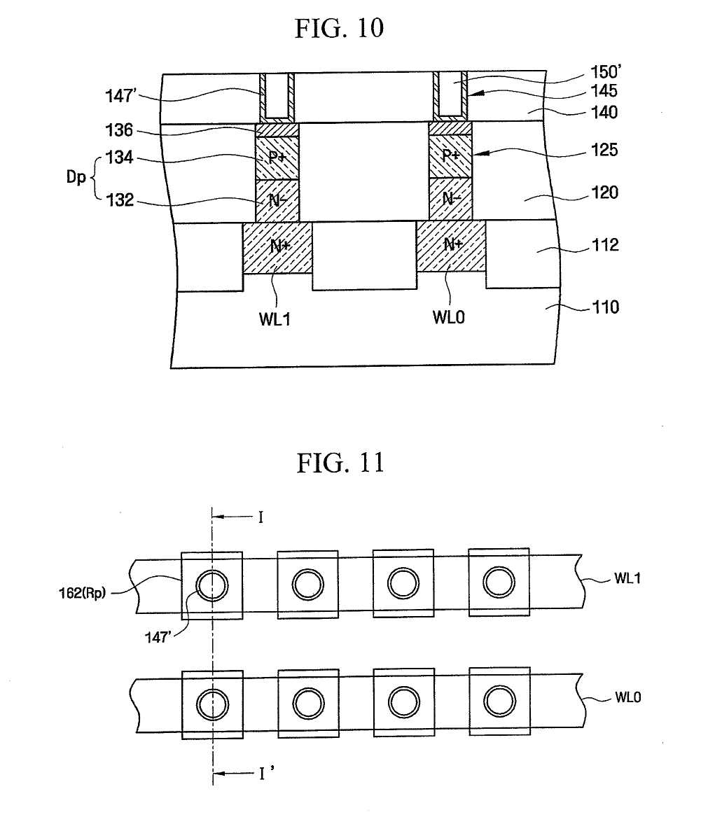

Referring to FIG. 10, the third insulating film pattern 150 and the bottom electrode film 147 are partially removed to form a bottom electrode 147′ on the diode electrode 136 and an insulating pattern 150′ within the bottom electrode 147′. For example, the third insulating film pattern 150 and the bottom electrode film 147 may be partially removed by a chemical mechanical polishing (CMP) process using the second insulating film pattern 140 as a polishing stop film. However, exemplary embodiments of the present invention are not limited thereto. The third insulating film pattern 150 and the bottom electrode film 147 may also be partially removed using a combination of, for example, an etch-back process and a CMP process.

If the CMP process is performed until a top surface of the second insulating film pattern 140 is exposed, portions of the third insulating film pattern 150 and the bottom electrode film 147 in the second apertures 145 may remain unremoved while portions thereof on the second insulating film pattern 140 are partially removed. Accordingly, the bottom electrode 147′ extending from the top surface of the diode electrode 136 to a top end of each of the second apertures 145 may be formed. A top surface of the bottom electrode 147′ may be at substantially the same level as the top surface of the second insulating film pattern 140.

In the current exemplary embodiment, the bottom electrode 147′ may have, for example, a cylindrical shape along the sidewalls of each of the second apertures 145, and the insulating pattern 150′ is formed in the cylindrical bottom electrode 147′ However, exemplary embodiments of the present invention are not limited thereto.

The bottom electrode 147′ may contact the diode electrode 136. When the diode electrode 136 is omitted, the bottom electrode 147′ may directly contact the second semiconductor pattern 134. For example, a surface of the cylindrical bottom electrode 147′ which is exposed through each of the second apertures 145 may be ring-shaped, and the area of the exposed surface may be smaller than that of a horizontal cross-section of each of the second apertures 145. However, exemplary embodiments of the present invention are not limited thereto.

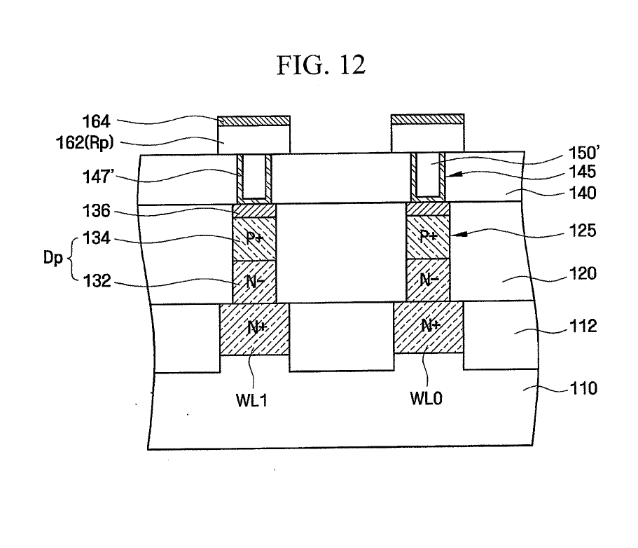

Referring to FIGS. 11 and 12, a phase-change material pattern 162 (Rₚ) and a top electrode contact 164 are formed on the bottom electrode 147′.

For example, a phase-change material film and a conductive film for forming the top electrode contact 164 are sequentially formed on the substrate 110 and then patterned to form the phase-change material pattern 162 (Rₚ) and the top electrode contact 164. Here, the phase-change material film may be formed using, for example, a physical vapor deposition technique such as a sputtering process with poor step coverage. Nonetheless, the phase-change material film may be formed to a uniform thickness over the entire substrate 110. This is because the substrate 110 having the bottom electrode 147′ in the current exemplary embodiment has, for example, a flat surface.

The phase-change material pattern 162 (Rₚ) may be made of various types of materials including, for example, a combination of two elements such as GaSb, InSb, InSe, Sb₂Te₃ or GeTe, a combination of three elements such as GeSbTe, GaSeTe, InSbTe, SnSb₂Te₄ or InSbGe, and a combination of four elements such as AgInSbTe, (GeSn)SbTe, GeSb(SeTe) or Te₈₁Ge₁₅Sb₂S₂. The top electrode contact 164 may be made of a material such as, for example, Ti/TiN.

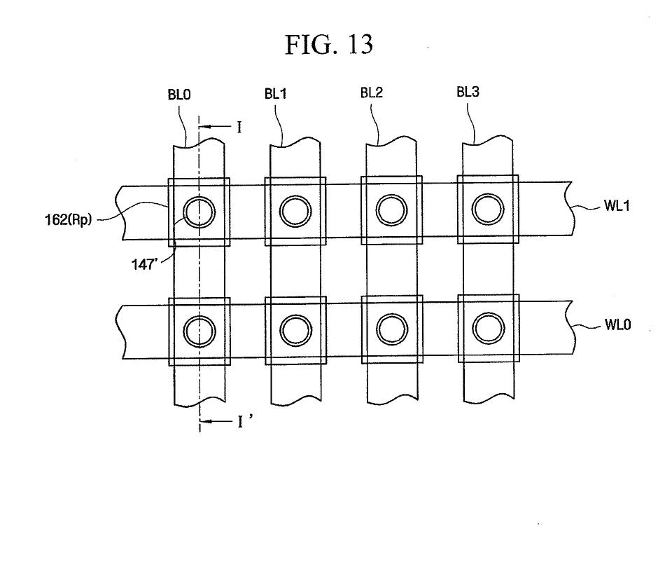

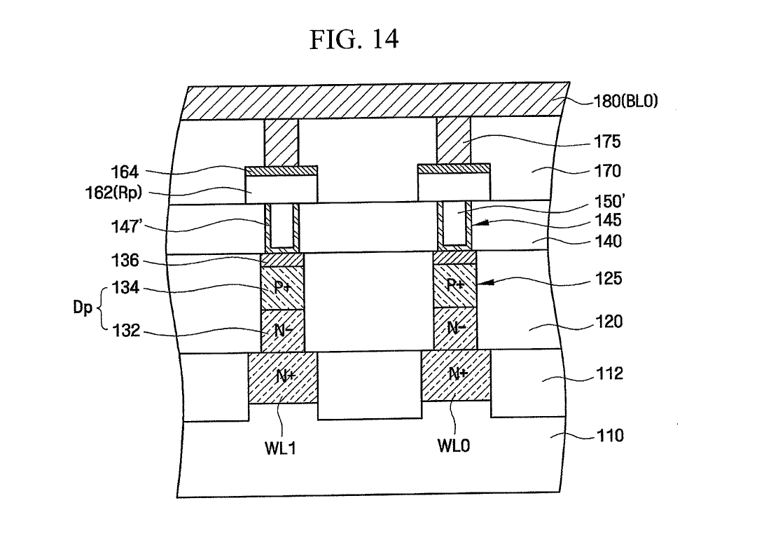

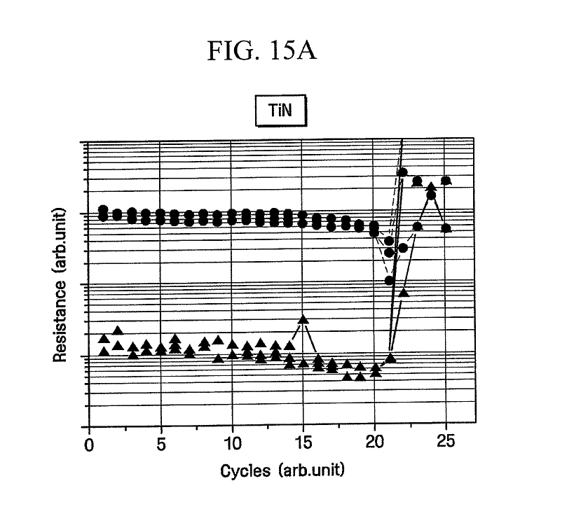

Referring to FIGS. 13 and 14, a top insulating film pattern 170 having contact holes is formed on the substrate 110 having the top electrode contact 164. A bit line contact plug 175 is formed in each of the contact holes to contact the top electrode contact 164. The bit lines BL0 through BL3 extending in the second direction are formed on the bit line contact plug 175. The bit lines BL0 through BL3 may be arranged to intersect the word lines WL0 and WL1. For example, FIG. 14 illustrates a cross-sectional view of bit line BL0 180 extending in the second direction and formed on the bit line contact plug 175 taken along I-I′ of FIG. 13.

The effects of a Si-doped TiN film will now be described using experimental data.

When a conventional TiN film is used as a bottom electrode of a PRAM, grain growth stress is generated during a programming operation of the PRAM. Accordingly, grains may grow in the TiN film. Since the boundary of grains has higher diffusivity than bulk, a phase-change material may readily flow to the bottom electrode along the boundary of the grains.

However, a Si-doped TiN film formed as described above is highly amorphous. Therefore, grain growth is minimized. Consequently, the durability of a memory device using the Si-doped TiN film is increased.

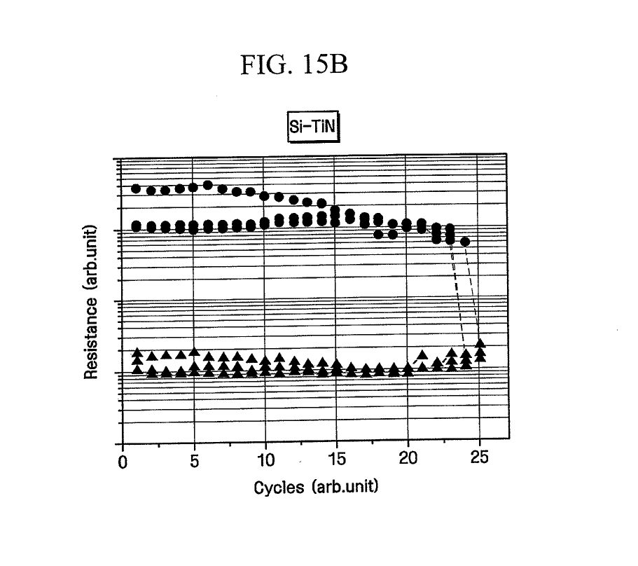

FIG. 15A is a graph illustrating the set-state (triangle dot) resistance and reset-state (circle dot) resistance of a TiN electrode deposited using a metal-organic deposition method. FIG. 15B is a graph illustrating the set-state (triangle dot) resistance and reset-state (circle dot) resistance of a Si-doped TiN electrode.

Referring to FIGS. 15A and 15B, it is shown that the Si-doped TiN electrode has greater durability than the TiN electrode deposited using a conventional metal-organic deposition method.

Having described exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A method of manufacturing a nonvolatile memory device, the method comprising:
forming an insulating film pattern, which comprises apertures, on a substrate;
forming a switching element in each of the apertures;
forming a bottom electrode on the switching element by using a silicon (Si)-doped titanium nitride (TiN) film; and
forming a variable resistance material pattern on the bottom electrode,
wherein the Si-doped TiN film is formed by repeatedly forming a TiN film and doping the TiN film with Si.

2. The method of claim 1, wherein the TiN film is formed by successively repeating a plurality of times an operation of depositing a TiN precursor using an atomic layer deposition (ALD) method and making the deposited TiN film react with a reaction gas.

3. The method of claim 2, wherein the TiN precursor is any one of tetrakis-(dimethylamino)-titanium (TDMAT), tetrakis-(diethylamino)-titanium (TDEAT), tetrakis-(ethylmethylamino)-titanium (TEMAT), and a combination of these materials.

4. The method of claim 2, wherein the reaction gas comprises at least one of ammonia (NH₃) and nitrogen (N₂).

5. The method of claim 1, wherein in the doping of the TiN film with Si, a Si precursor is made to react with the TiN film using an atomic layer deposition (ALD) method.

6. The method of claim 5, wherein the Si precursor is any one of bis-(tert-butylamino)-silane (BTBAS), tris-(dimethylamino)-silane (3DMAS), tetrakis-(tert-butylamino)-silane (TTBAS), and a combination of these materials.

7. A method of forming a titanium nitride (TiN) film, the method comprising:
successively performing a plurality of times a first operation of depositing a TiN precursor using an atomic layer deposition (ALD) method and making the deposited TiN precursor react with a reaction gas; and
successively performing a plurality of times a second operation of making a silicon (Si) precursor react with the TiN film using the ALD method.

8. The method of claim 7, wherein the second operation further comprises purging the Si precursor which remains after reacting with the TiN film.

9. The method of claim 7, wherein the first operation further comprises purging the TiN precursor which remains after being deposited and purging the reaction gas after the deposited TiN precursor is made to react with the reaction gas.

10. The method of claim 7, wherein the TiN precursor is any one of tetrakis-(dimethylamino)-titanium (TDMAT), tetrakis-(diethylamino)-titanium (TDEAT), tetrakis-(ethylmethylamino)-titanium (TEMAT), and a combination of these materials.

11. The method of claim 7, wherein the reaction gas comprises at least one of ammonia (NH₃) and nitrogen (N₂).

12. The method of claim 7, wherein the Si precursor is any one of bis-(tert-butylamino)-silane (BTBAS), tris-(dimethylamino)-silane (3DMAS), tetrakis-(tert-butylamino)-silane (TTBAS), and a combination of these materials.

13. A method of manufacturing a nonvolatile memory device, the method comprising:
forming a plurality of element isolation regions in a substrate of a first conductivity type to define a plurality of active regions therein;
forming a plurality of word lines in the active regions;
forming a first insulating pattern having a plurality of first apertures on the substrate, wherein the first apertures expose a respective one of each of the word lines;
forming a first semiconductor pattern and a second semiconductor pattern sequentially stacked in each of the first apertures to thereby form a vertical cell diode in each of the first apertures and on a respective one of each of the word lines;
forming a diode electrode on each of the vertical cell diodes;
forming a second insulating film pattern having a plurality of second apertures on the first insulating film pattern, wherein the second apertures each expose a respective one of each of the diode electrodes;
forming a bottom electrode film formed of a silicon (Si)-doped titanium nitride (TiN) film on a top surface of the second insulating film pattern, on a top surface of each of the diode electrodes and covering sidewalls of each the second apertures;
forming a third insulating film pattern on the bottom electrode film filling each of the second apertures;
partially removing the bottom electrode film and the third insulating film pattern to form a bottom electrode on each of the diode electrodes and an insulating pattern within a respective one of each of the bottom electrodes;
sequentially forming a phase-change material pattern and a top electrode contact on each of the bottom electrodes;
forming a top insulating film pattern having contact holes therein on the substrate having the top electrode contacts;
forming a bit line contact plug in each of the contact holes to contact a respective one of each of the top electrode contacts; and
forming a bit line on the bit line contact plugs and intersecting the word lines.

14. The method of claim 13, wherein the forming of the word lines comprises implanting ions of a second conductivity type into the actives regions.

15. The method of claim 14, wherein an impurity concentration of the first semiconductor pattern is lower than an impurity concentration of the word lines, and wherein an impurity concentration of the second semiconductor pattern is higher than the impurity concentration of the first semiconductor pattern.

16. The method of claim 13, wherein the first and second semiconductor patterns are grown by one of a selective epitaxial growth (SEG) method or solid phase epitaxial growth (SPEG) method.

17. The method of claim 13, wherein the bottom electrode film composed of the Si-doped TiN film is formed by successively repeating a plurality of times a first operation of depositing a TiN precursor using an atomic layer deposition (ALD) method and making the deposited TiN film react with a reaction gas and successively performing a plurality of times a second operation of doping the TiN film with a Si precursor using the ALD method to react with the TiN film.

18. The method of claim 17, wherein the TiN precursor is any one of tetrakis-(dimethylamino)-titanium (TDMAT), tetrakis-(diethylamino)-titanium (TDEAT), tetrakis-(ethylmethylamino)-titanium (TEMAT), and a combination of these materials, wherein the reaction gas comprises at least one of ammonia (NH₃) and nitrogen (N₂), and wherein the Si precursor is any one of bis-(tert-butylamino)-silane (BTBAS), tris-(dimethylamino)-silane (3DMAS), tetrakis-(tert-butylamino)-silane (TTBAS), and a combination of these materials.

19. The method of claim 13, wherein the partially removing of the third insulating film pattern and the bottom electrode film results in a top surface of the bottom electrode being formed at substantially a same level as a top surface of the second insulating film pattern.

20. The method of claim 17, wherein the TiN precursor in the first operation is deposited at a temperature of no greater than about 420° C.
